(19) United States
(12) Patent Application Publication
(10) Pub. No.: US 2026/0011597 A1
(43) Pub. Date: Jan. 8, 2026

(54) TEMPORARY FIXATION SUBSTRATE AND METHOD OF MANUFACTURING TEMPORARY FIXATION SUBSTRATE

(71) Applicant: NGK INSULATORS, LTD., Nagoya-shi (JP)

(72) Inventors: Masaru NOMURA, Owariasahi-shi (JP); Daisuke YABU, Nagoya-shi (JP)

(21) Appl. No.: 19/326,939

(22) Filed: Sep. 12, 2025

Related U.S. Application Data
(63) Continuation of application No. PCT/JP2024/008119, filed on Mar. 4, 2024.

(30) Foreign Application Priority Data
Mar. 17, 2023 (JP) 2023-042969

(51) Int. Cl. H01L 21/683

(52) U.S. Cl. CPC H01L 21/6835; H01L 2221/68318; H01L 2221/68354; H01L 2221/68386

(57) ABSTRACT

A temporary fixation substrate, peeled from a predetermined object to be fixed after once the predetermined object to be fixed is temporarily fixed to one main surface thereof, includes: a thin region being an annular region having a predetermined width from a lateral end; and a first thickness-reduced portion having been recessed from the one main surface on a side of the one main surface in the thin region, wherein a thickness in the thin region is smaller than a thickness in a region other than the thin region, and a difference between a thickness at the lateral end and the thickness in the region other than the thin region is 1 μm to 5 μm.

### CROSS-REFERENCE TO RELATED APPLICATION

This application is a continuation application of PCT/JP2024/008119, filed on Mar. 4, 2024, which claims the benefit of priority of Japanese Application No. 2023-042969, filed on Mar. 17, 2023, the entire contents of which are incorporated herein by reference.

### BACKGROUND

### Technical Field

The present disclosure relates to a temporary fixation substrate for use in a process for manufacturing a semiconductor package.

### Description of the Background Art

Fan-out wafer level packaging (FOWLP) technology is known as technology for manufacturing a semiconductor package. The FOWLP technology generally includes a step of performing resin molding on a temporary fixation substrate to which semiconductor chips have temporarily been fixed with an adhesive, a step of grinding a resin mold to expose electrode ends of the semiconductor chips, a step of forming a thin-film redistribution layer (multilayer wiring) and a solder ball on a surface from which the electrode ends are exposed, and a step of singulating each package and peeling the package from the temporary fixation substrate to obtain a semiconductor package having a lower profile.

Use of a translucent ceramic substrate as a temporary fixation substrate for chips in the FOWLP technology has already been known (see Japanese Patent No. 6430081 and Japanese Patent No. 6420023, for example).

Joining a pre-warped support substrate formed of glass or ceramics to a silicon substrate with a thermosetting resin to obtain a joined body and laminating a minimally-warped glass substrate with a thin film as obtained to a surface of another member have already been known (see Japanese Patent Application Laid-Open No. 2011-23438 and Japanese Patent Application Laid-Open No. 2010-58989, for example).

The temporary fixation substrate is peeled in the FOWLP technology by irradiation with light from a light source, such as a laser light source and a lamp. A scheme of performing peeling by irradiation with light from the laser light source is so-called laser lift-off. That is to say, interfaces (adhered surfaces with an adhesive) between the temporary fixation substrate and semiconductor chips and a resin as objects to be fixed are irradiated with light, such as a laser, from a side of the temporary fixation substrate to ablate the adhesive to thereby peel the temporary fixation substrate. In irradiation with light, it is required to prevent a failure that a resin, an adhesive, and the like of a semiconductor package remain on the temporary fixation substrate.

Furthermore, there is a need to peel the support substrate and the like after manufacture of the joined body and the laminated substrate as disclosed in Japanese Patent Application Laid-Open No. 2011-23438 and Japanese Patent Application Laid-Open No. 2010-58989. The support substrate and the like can be considered as the temporary fixation substrate. Also when irradiation with light is adopted to peel such a support substrate and the like, remaining of a resin and the like used for adhesion on the support substrate and the like is not preferable.

As a result of diligent examination, the inventors of the present disclosure have found that reliability of peeling of the temporary fixation substrate increases with increasing transmission of light, such as a laser, at a circumference.

### SUMMARY

The present disclosure relates to a temporary fixation substrate for use in a process for manufacturing a semiconductor package and, in particular, to a shape thereof.

According to the present disclosure, a temporary fixation substrate, peeled from a predetermined object to be fixed after once the predetermined object to be fixed is temporarily fixed to one main surface thereof, includes: a thin region being an annular region having a predetermined width from a lateral end; and a first thickness-reduced portion on a side of the one main surface in the thin region, the first thickness-reduced portion having been recessed from the one main surface. A thickness in the reduced thickness region is smaller than a thickness in a region other than the thin region, and a difference between a thickness at the lateral end and the thickness in the region other than the thin region is 1 μm to 5 μm.

The temporary fixation substrate used for temporary fixation of the object to be fixed, such as semiconductor chips, includes the thin region at an entire circumference of a surface to which the object to be fixed is mounted, so that the temporary fixation substrate can suitably be peeled from the semiconductor chips and a resin mold using a light source.

### BRIEF DESCRIPTION OF THE DRAWINGS

FIG. 1 is a plan view of one main surface (a front surface) 1a of a temporary fixation substrate 1;

FIGS. 2A to 2D are partial cross-sectional views near lateral ends 1e of various types of temporary fixation substrates 1;

FIGS. 3A to 3C are schematic cross-sectional views illustrating steps during a process for preparing a semiconductor package with FOWLP technology using the temporary fixation substrate 1;

FIGS. 4A to 4C are schematic cross-sectional views illustrating steps during the process for preparing the semiconductor package with the FOWLP technology using the temporary fixation substrate 1;

FIG. 5 is a flowchart generally showing a process for manufacturing the temporary fixation substrate 1;

FIGS. 6A to 6C are diagrams schematically showing preparation of a molded body 1α by mold casting;

FIGS. 7A and 7B are diagrams showing use of a molded body 1β prepared by tape molding for preparation of a temporary fixation substrate 1 including a front side thickness-reduced portion 2a in the stepped shape; and

FIG. 8 is a diagram illustrating measurement positions of a front recess amount Δta.

### DESCRIPTION OF THE PREFERRED EMBODIMENTS

### Temporary Fixation Substrate

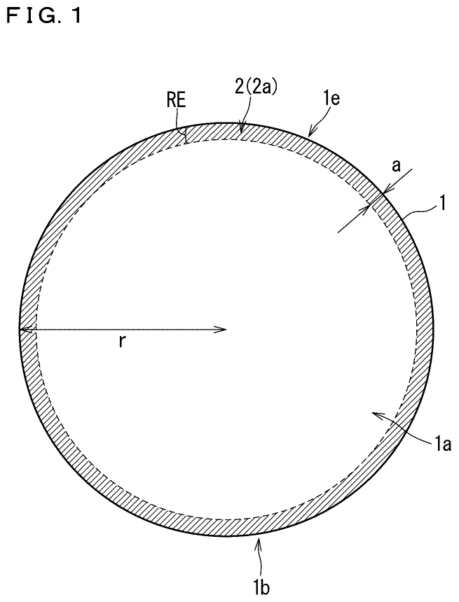

FIG. 1 is a plan view of one main surface (a front surface) 1a of a temporary fixation substrate 1 as one aspect of a support substrate according to the present disclosure. The temporary fixation substrate 1 is a substrate to which semiconductor chips are temporarily fixed in preparing a semiconductor package with fan-out wafer level packaging (FOWLP) technology, for example.

The temporary fixation substrate 1 is a disc-shaped translucent ceramic substrate having a diameter of several hundred millimeters (e.g., 300 mm), a thickness of approximately several hundred micrometers to several millimeters (e.g., 1 mm), an in-plane thickness difference of several micrometers or less (e.g., 3 μm or less), and a warpage amount of several hundred micrometers or less (e.g., 200 μm). Assume that translucent ceramics are ceramics having a forward total light transmittance of 20% or more in a full wavelength range of 200 nm to 1500 nm in the present embodiment. Examples of such translucent ceramics include alumina, silicon nitride, aluminum nitride, and silicon oxide. One suitable example of the temporary fixation substrate 1 is a temporary fixation substrate containing alumina as a major component and having a forward total light transmittance of 70% or more at a wavelength of 1500 nm, for example. When the temporary fixation substrate 1 contains alumina as a major component, alumina powder having a high purity of 99.9% or more (preferably 99.95% or more) is preferably used as a raw material, and magnesium oxide and zirconia (ZrO₂) or yttria (Y₂O₃) as a sintering agent are preferably added to the alumina powder.

The front surface 1a as a surface over which the semiconductor chips are arranged as well as the other main surface (a rear surface) 1b are polished in advance to be flat polished surfaces each having a small surface roughness. More particularly, the front surface 1a and the rear surface 1b each have the above-mentioned in-plane thickness difference of several micrometers or less and an arithmetic average roughness Ra of 100 nm or less (preferably 20 nm or less). More specifically, the front surface 1a and the rear surface 1b are lapped surfaces. While there is no particular limitation on a lower limit of the arithmetic average roughness Ra of each of the front surface 1a and the rear surface 1b, an arithmetic average roughness Ra of 1 nm will suffice for practical use.

The temporary fixation substrate 1 according to the present embodiment includes, in an annular region having a predetermined width “a” from a lateral end 1e over an entire circumference of the front surface 1a, a thickness-reduced portion 2 (2a) having been recessed from the other portion (i.e., having a lower height in a direction of a thickness of the substrate). Although not illustrated, the temporary fixation substrate 1 may include a thickness-reduced portion 2 (2b) similarly over an entire circumference of the rear surface 1b.

The annular region having the width “a” from the lateral end 1e in which the thickness-reduced portion 2 is formed is hereinafter referred to as a thin region RE. Particularly, while the above-mentioned thickness of the temporary fixation substrate 1 of approximately several hundred micrometers to several millimeters is originally a distance between the front surface 1a and the rear surface 1b in a region other than the thin region RE, a difference between a thickness in the thin region RE and a thickness in the other region is small as will be described below. It can thus be said that the temporary fixation substrate 1 including the thin region RE virtually has a thickness of approximately several hundred micrometers to several millimeters. Assume that the above-mentioned arithmetic average roughness Ra of 100 nm or less of each of the front surface 1a and the rear surface 1b is achieved at least in regions of the front surface 1a and the rear surface 1b other than the thin region RE.

The thickness-reduced portion 2 is formed with the intension to ensure that peeling by irradiation with light from a light source is suitably performed, wherein the peeling is one step in a process for preparing the semiconductor package using the temporary fixation substrate 1 described in detail below.

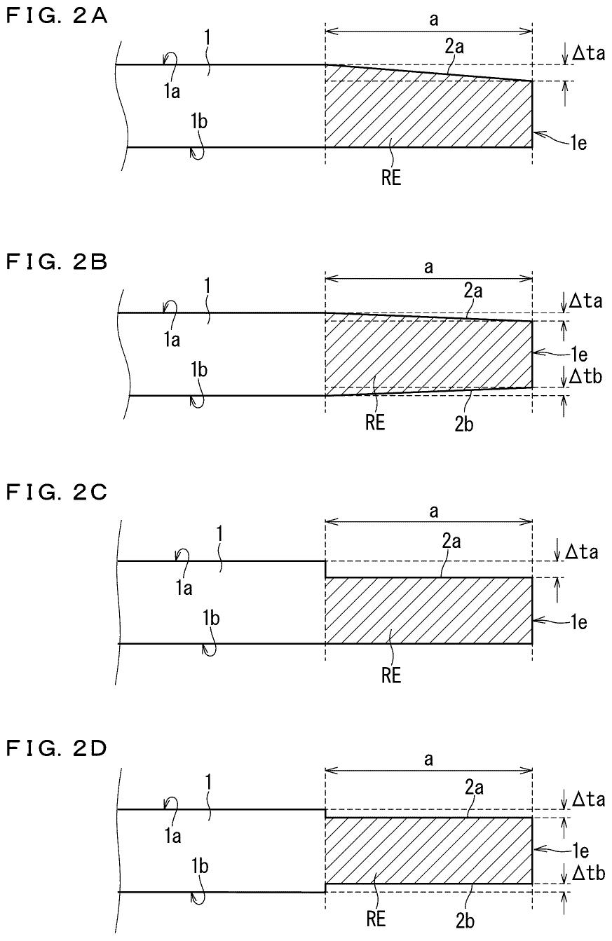

FIGS. 2A to 2D are partial cross-sectional views near lateral ends 1e of various types of temporary fixation substrates 1 to illustrate specific aspects of formation of the thickness-reduced portion 2. Assume that any of the temporary fixation substrates 1 includes the thickness-reduced portion 2 in the thin region RE having the predetermined width “a”.

FIG. 2A is a diagram illustrating a temporary fixation substrate 1 including a front side thickness-reduced portion 2a in a tapered shape at a circumference of the front surface 1a.

FIG. 2B is a diagram illustrating a temporary fixation substrate 1 including the front side thickness-reduced portion 2a in the tapered shape at the circumference of the front surface 1a and a rear side thickness-reduced portion 2b in a tapered shape at a circumference of the rear surface 1b.

FIG. 2C is a diagram illustrating a temporary fixation substrate 1 including a front side thickness-reduced portion 2a in a stepped shape at the circumference of the front surface 1a.

FIG. 2D is a diagram illustrating a temporary fixation substrate 1 including the front side thickness-reduced portion 2a in the stepped shape at the circumference of the front surface 1a and a rear side thickness-reduced portion 2b in a stepped shape at the circumference of the rear surface 1b.

An equation Δt=Δta holds true when only the front side thickness-reduced portion 2a is formed as illustrated in FIGS. 2A and 2C, and an equation Δt=Δta+Δtb holds true when the front side thickness-reduced portion 2a and the rear side thickness-reduced portion 2b are formed as illustrated in FIGS. 2B and 2D, where Δt is a total recess amount as a difference between the thickness of the temporary fixation substrate 1 in the region other than the thin region RE and a thickness of the temporary fixation substrate 1 at the lateral end 1e, Δta is a front recess amount as a distance between the front surface 1a and the lateral end 1e in the direction of the thickness in the front side thickness-reduced portion 2a, and Δtb is a rear recess amount as a distance between the rear surface 1b and the lateral end 1e in the direction of the thickness in the rear side thickness-reduced portion 2b.

The total recess amount Δt corresponds to a maximum value of a difference between the thickness in the thin region RE and the thickness in the other region. When the front side thickness-reduced portion 2a and the rear side thickness-reduced portion 2b are stepped, the front recess amount Δta and the rear recess amount Δtb correspond to distances of steps of the respective thickness-reduced portions.

It is not limited that the thickness-reduced portion 2 is formed in a tapered or stepped shape, and the thickness-reduced portion 2 may have a curved surface which is convex upward or downward when viewed in cross section. The front side thickness-reduced portion 2a and the rear side thickness-reduced portion 2b may have different shapes.

### Process for Preparing Semiconductor Package and Effect of Formation of Thickness-Reduced Portion

The thickness-reduced portion 2 is provided in the temporary fixation substrate 1 in a manner described above, and this is with the intention to ensure that peeling of the temporary fixation substrate 1 by irradiation with light as one step in the process for preparing the semiconductor package is suitably performed, and thereby to secure a manufacturing yield of the semiconductor package. This will be described below.

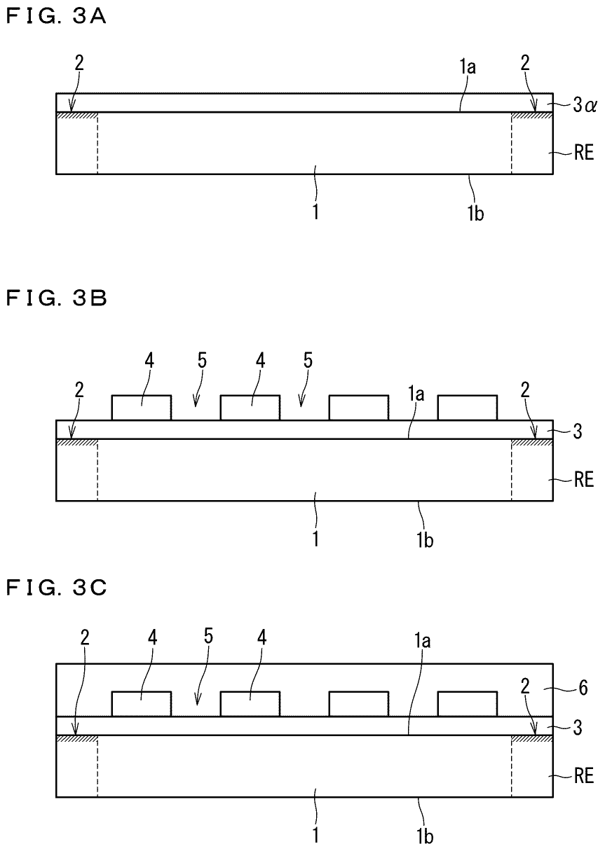

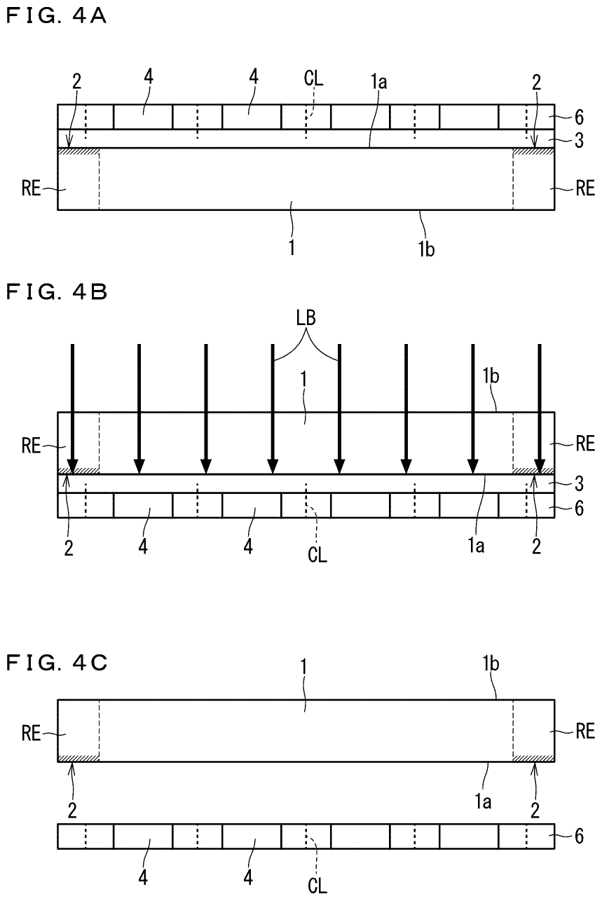

FIGS. 3A to 3C and 4A to 4C are schematic cross-sectional views illustrating steps during the process for preparing the semiconductor package with the FOWLP technology using the temporary fixation substrate 1. The thickness-reduced portion 2 is hatched only on a side of the front surface 1a in each of FIGS. 3A to 3C and 4A to 4C for ease of illustration and description.

In the process for preparing the semiconductor package, a layer formed of an adhesive (an adhesive layer) 3α is first formed over the temporary fixation substrate 1 as illustrated in FIG. 3A. Examples of the adhesive include double-sided tape and a hot melt-based adhesive, and various known schemes, such as roll coating, spray coating, screen printing, and spin coating, are applicable to formation of the adhesive. While the temporary fixation substrate 1 is particularly slightly warped to be convex on a side of the front surface 1a, the warpage is not illustrated in each of FIGS. 3A to 3C for the purposes of illustration.

Next, as illustrated in FIG. 3B, a plurality of (many) semiconductor chips 4 are arranged over the adhesive layer 3α. Although not illustrated in FIG. 3B, the semiconductor chips 4 are arranged also in the thin region RE. The adhesive layer 3α is then cured into an adhering layer 3. A curing scheme is selected from heating, ultraviolet irradiation, and the like according to a material for the adhesive used for the adhesive layer 3α and the like. The semiconductor chips 4 are thereby adhesively fixed to the temporary fixation substrate 1.

When the semiconductor chips 4 are fixed to the temporary fixation substrate 1 as described above, a molding resin is cast onto an entire upper surface of the temporary fixation substrate 1, that is, onto gaps 5 between the semiconductor chips 4 and entire upper surfaces of the semiconductor chips 4. The molding resin is cured into a resin mold 6 as illustrated in FIG. 3C. Examples of the molding resin include an epoxy-based resin, a polyimide-based resin, a polyurethane-based resin, and a urethane-based resin.

Next, the resin mold 6 is ground until electrode ends of the semiconductor chips 4 are exposed. The resin mold 6 can be ground, for example, by a grinder. FIG. 4A illustrates a state after grinding. Although not illustrated in FIGS. 4A to 4C, device components, such as a redistribution layer and a solder ball, are formed over the semiconductor chips 4 exposed by grinding.

Cut lines CL for singulation into a plurality of semiconductor packages each including a semiconductor chip 4 are formed in the resin mold 6. The cut lines CL are formed by a scheme such as dicing.

Finally, the temporary fixation substrate 1 is peeled (separated) by irradiation with light. That is to say, as illustrated in FIG. 4B, a portion of the adhering layer 3 on a side of the temporary fixation substrate 1 is irradiated with light LB from a laser light source, a lamp, and the like, for example. Examples of the light LB include UV light in a wavelength range of 200 nm to 400 nm and IR light in a wavelength range of 900 nm to 1200 nm. Examples of a light source for irradiation with such light include a UV lamp, a UV laser, and an IR laser.

The light LB passes through the temporary fixation substrate 1 as the translucent ceramic substrate and is absorbed by the adhering layer 3. The adhering layer 3 is thereby ablated (melted and evaporated), so that the temporary fixation substrate 1 is peeled from the semiconductor chips 4 and the resin mold 6 as illustrated in FIG. 4C. Furthermore, individual semiconductor packages are separated at the cut lines CL.

In the present embodiment, the use of the temporary fixation substrate 1 including the thickness-reduced portion 2 at the circumference contributes to better and surer peeling of the temporary fixation substrate 1 by irradiation with light.

When a transmissive object is irradiated with the light LB, a portion having a smaller thickness has higher transmission of the light LB. The temporary fixation substrate 1 according to the present embodiment thus has higher transmission of the light LB in the thin region RE at the circumference than in the other region (e.g., a central region). A circumferential portion of the temporary fixation substrate 1 irradiated with the light LB is thus preferentially peeled, peeling progresses from the circumferential portion, and better and surer peeling without adhesion (remaining) of the resin is eventually achieved. This is achieved regardless of a form of the light source, that is, whether the light source is a lamp or a laser light source, as long as the light LB in the above-mentioned wavelength range is emitted.

Transmission of the light LB increases with increasing total recess amount Δt, but, when the semiconductor chips 4 are arranged in the thin region RE having an excessively large front recess amount Δta, surfaces of the semiconductor chips 4 arranged in the thin region RE might not be exposed in grinding the resin mold 6 prior to irradiation with light. The presence of any semiconductor chip 4 whose front surface is not exposed is not preferable because a failure of connection between the semiconductor chip 4 and the redistribution layer occurs in forming the redistribution layer. On the other hand, an effect of forming the front side thickness-reduced portion 2a is not obtained when the front recess amount Δta is less than 1 μm. In view of the foregoing, the front recess amount Δta is 1 μm to 5 μm.

The rear recess amount Δtb when the rear side thickness-reduced portion 2b is formed is not required to consider interference as described above and is only required to be determined so that the total recess amount Δt has a value of approximately 1 μm to 5 μm while the front recess amount Δta is 1 μm or more for practical use.

In other words, the temporary fixation substrate 1 according to the present embodiment has a thickness at the lateral end 1e 1 μm to 5 μm smaller than the thickness in the region other than the thin region RE.

On the other hand, a range having excellent transmission of the light LB increases with increasing width “a” of the thin region RE, but the width “a” of up to 3% of a radius r of the temporary fixation substrate 1 will suffice from a standpoint of securement of peeling property. A width “a” of more than 3% of the radius r increases the number of semiconductor chips 4 arranged in the thin region RE and increases the risk of a failure of grinding. On the other hand, a width “a” of less than 0.5% of the radius r cannot produce an effect of suppressing a failure of peeling obtained by forming the thin region RE including the front side thickness-reduced portion 2a. In view of the foregoing, the thin region RE has a width “a” that is 0.5% to 3% of the radius r of the temporary fixation substrate 1.

### Process for Manufacturing Temporary Fixation Substrate

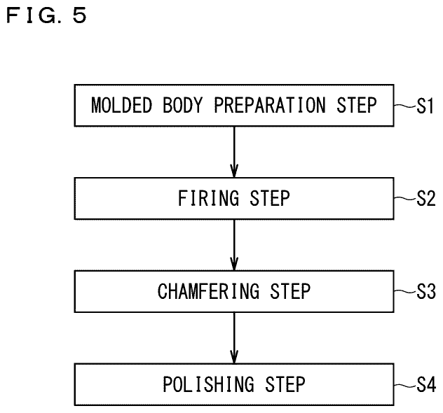

A process for manufacturing the temporary fixation substrate 1 having the thickness-reduced portion 2 will be described next. FIG. 5 is a flowchart generally showing the process for manufacturing the temporary fixation substrate 1. The temporary fixation substrate 1 is generally manufactured through a molded body preparation step (step S1), a firing step (step S2), a chamfering step (step S3), and a polishing step (step S4).

In manufacturing the temporary fixation substrate 1, a molded body containing translucent ceramic powder as a major component is first prepared (step S1). Examples of a method of preparing the molded body include mold casting and tape molding.

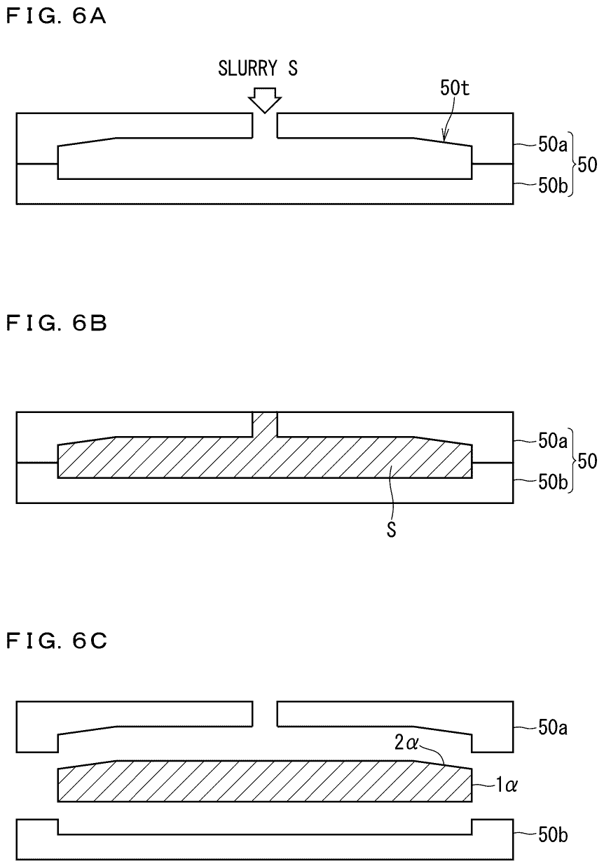

FIGS. 6A to 6C are diagrams schematically showing preparation of a molded body 1α by mold casting. FIGS. 6A to 6C illustrate procedures for preparing the molded body 1α to obtain the temporary fixation substrate 1 including the front side thickness-reduced portion 2a in the tapered shape as illustrated in FIG. 2A.

First, a mold 50 including a top mold 50a and a bottom mold 50b as illustrated in FIG. 6A is prepared. In the mold 50, the top mold 50a and the bottom mold 50b are integrated to form a disc-shaped internal space 50s corresponding to the molded body 1α to be prepared. A top circumferential portion of an inner surface of the top mold 50a forming the internal space 50s includes a tapered portion 50t corresponding to the front side thickness-reduced portion 2a.

A slurry S as a raw material for the temporary fixation substrate 1 is injected into the internal space 50s through an inlet 50c formed in the top mold 50a to cast the slurry S.

The slurry S is prepared by mixing the above-mentioned translucent ceramic raw material powder of alumina and the like, ceramic powder such as magnesia and a sintering agent, and an organic material such as a dispersion medium, a gelling agent, a dispersing agent, and a catalyst in a ball mill and the like, for example.

As illustrated in FIG. 6B, the slurry S injected into the internal space 50s is allowed to stand for a predetermined time period according to a predetermined temperature profile to set. The top mold 50a and the bottom mold 50b are released midway as illustrated in FIG. 6C. The molded body 1α including a tapered thickness-reduced portion 2α in the circumferential portion of the upper surface is eventually obtained.

In the case that the front side thickness-reduced portion 2a is formed in the stepped shape, or the rear side thickness-reduced portion 2b is formed in addition to the front side thickness-reduced portion 2a, a mold 50 conforming to the formed portion is used.

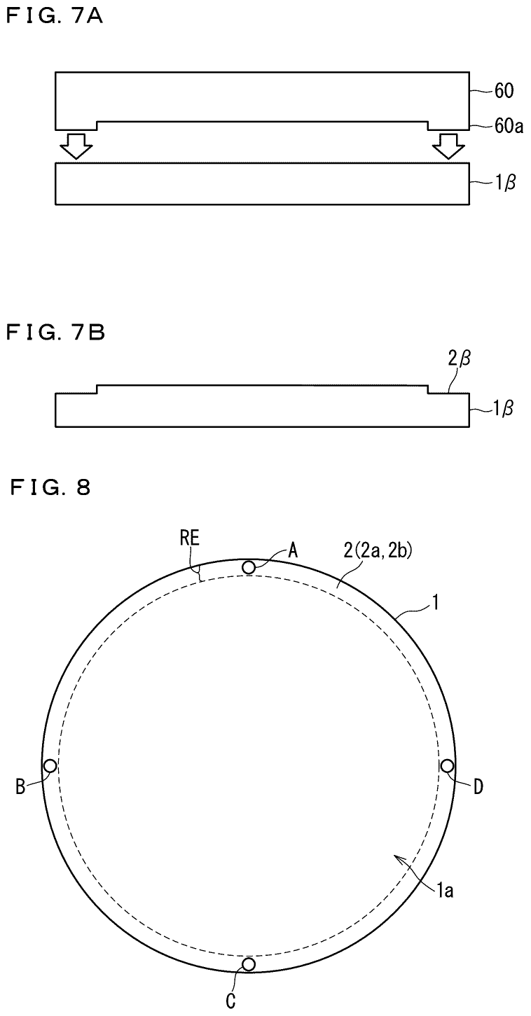

On the other hand, FIGS. 7A and 7B are diagrams showing use of a molded body 1β prepared by tape molding for preparation of the temporary fixation substrate 1 including the front side thickness-reduced portion 2a in the stepped shape as with the temporary fixation substrate 1 illustrated in FIG. 2C.

When the molded body 1β is prepared by tape molding, the slurry prepared as described above is molded into tape. A plurality of rectangular sheets each having a predetermined size obtained by shearing (cutting) the obtained tape are laminated and pressed, and a laminate after pressing is die cut into a circular shape. A disc-shaped molded body 1β is thereby obtained.

As illustrated in FIG. 7A, a circumferential portion of the disc-shaped molded body 1β is pressed (deformed) by a press mold 60 having a pressing portion 60a corresponding to the circumferential portion to form a thickness-reduced portion 2β in a stepped shape of the molded body 1β as illustrated in FIG. 7B.

In the case that the front side thickness-reduced portion 2a is formed in the tapered shape, or the rear side thickness-reduced portion 2b is formed in addition to the front side thickness-reduced portion 2a, a press mold 60 conforming to the formed portion is used.

In any case, in the molded body preparation step, a size and a shape of the molded body including a form of the thickness-reduced portion 2α and a form of the thickness-reduced portion 2β are determined in view of firing shrinkage in the firing step. That is to say, the size and the shape of the molded body are determined to eventually obtain the temporary fixation substrate 1 having a desired shape.

The molded body 1α prepared by mold casting without forming the front side thickness-reduced portion 2a and further the rear side thickness-reduced portion 2b may be pressed (deformed) by the press mold 60 to form the front side thickness-reduced portion 2a and further the rear side thickness-reduced portion 2b.

The molded body may alternatively be obtained by doctor blading, extrusion, and the like.

Next, the prepared molded body is fired (step S2). In the firing step, an organic component is desorbed to obtain a sintered body of ceramics (the temporary fixation substrate 1 before chamfering and polishing). Firing is preferably performed by performing temporary firing in an atmospheric furnace and then performing main firing in a hydrogen furnace. A sintering temperature during main firing is preferably 1700° C. to 1900° C. and is more preferably 1750° C. to 1850° C. in terms of densification of the sintered body.

After main firing, the obtained sintered body may further be annealed in the hydrogen furnace for the purpose of adjusting (correcting) warpage. Annealing is preferably performed at a temperature within ±100° C. with respect to a maximum temperature in main firing and is more preferably performed at 1900° C. or less in terms of facilitating discharge of the sintering agent while preventing deformation and growth of abnormal particles. Annealing is preferably performed for one to six hours.

When the sintered body (the temporary fixation substrate 1 before chamfering and polishing) is obtained, an edge (a corner) of the sintered body is chamfered (beveled) next (step S3). Chamfering is performed to suppress chipping at the corner of the temporary fixation substrate 1.

Finally, the front surface and the rear surface (opposite main surfaces) of the temporary fixation substrate 1 after chamfering are polished (step S4). An example of polishing is lapping using a diamond slurry.

The temporary fixation substrate 1 including the front side thickness-reduced portion 2a, or further including the rear side thickness-reduced portion 2b, in the thin region RE is obtained through the above-mentioned steps.

As described above, according to the present embodiment, the temporary fixation substrate used to temporarily fix the semiconductor chips in the process for preparing the semiconductor package with the FOWLP technology includes the thin region at least having the predetermined width from the lateral end of the temporary fixation substrate, thereby to suitably peel the temporary fixation substrate from the semiconductor chips and the resin mold by irradiation with light from the light source.

### Modifications

While the temporary fixation substrate including the thickness-reduced portion is used as the substrate to which the plurality of semiconductor chips are temporarily fixed in preparing the semiconductor package with the FOWLP technology in the above-mentioned embodiment, a use aspect of the temporary fixation substrate is not limited to this aspect, and the temporary fixation substrate may be used to temporarily fix an electronic component other than the semiconductor chips. That is to say, the temporary fixation substrate according to the above-mentioned embodiment may be used for the purpose of suitably peeling the temporary fixation substrate by laser lift-off in the case that the resin mold is formed after a plurality of electronic components are adhered to the temporary fixation substrate with an adhesive.

Alternatively, in the case that a predetermined support substrate is peeled by laser lift-off from a joined body in which various substrates have been joined to the support substrate with an adhesive, the support substrate may include the thin region at a circumference in advance. Examples of the substrates joined to the support substrate include various substrates including a silicon substrate, a compound semiconductor substrate, an epitaxial substrate, or other composite substrates, double-layer substrates, multi-layer substrates, and the like. An effect similar to the effect obtained in the above-mentioned embodiment can be obtained also in this case.

### EXAMPLES

For each of six types of temporary fixation substrates 1 differing in shape in the thin region RE and in total recess amount Δt in a range of 1 μm to 5 μm (Examples 1 to 6), 200 temporary fixation substrates 1 were prepared. Steps to irradiation with light were sequentially performed according to the above-mentioned process for preparing the semiconductor package using each of the obtained temporary fixation substrates 1. As a scheme of irradiation with light, laser lift-off with UV laser light (wavelength: 200 nm to 400 nm) was adopted. Based on results thereof, grindability of the resin mold 6 and peeling property of the temporary fixation substrate 1 by laser lift-off were evaluated.

A temporary fixation substrate 1 having a total recess amount Δt of more than 5 μm was prepared as Comparative Example 1, and a temporary fixation substrate 1 not including the front side thickness-reduced portion 2a and the rear side thickness-reduced portion 2b and therefore not having the reduced thickness region RE (i.e., having a total recess amount Δt of zero) was prepared as Comparative Example 2, and grindability of the resin mold 6 and peeling property of the temporary fixation substrate 1 by laser lift-off were evaluated as in Examples 1 to 6.

That is to say, for each of Examples 1 to 6 and Comparative Examples 1 and 2, 200 test samples were prepared, and, based on these test samples, grindability of the resin mold 6 and peeling property of the temporary fixation substrate 1 by laser lift-off were evaluated.

As a raw material for the temporary fixation substrate 1, α-alumina powder having a specific surface area of 3.5 m²/g to 4.5 m²/g and an average primary particle size of 0.35 μm to 0.45 μm was used as the translucent ceramic raw material powder, magnesia powder was used as the other ceramic powder, and zirconia powder and yttria powder were used as the sintering agent.

Dimethyl glutarate and ethylene glycol were used as dispersion media. An MDI resin was used as the gelling agent. A high molecular surface active agent was used as the dispersing agent. N, N-dimethylaminohexanol was used as the catalyst.

These raw materials were mixed, to obtain a slurry for preparation of the molded body, at a weight rate as described below:
α-alumina powder: 100 pts·wt.;
magnesia: 0.025 pts·wt.;
zirconia: 0.040 pts·wt.;
yttria: 0.0015 pts·wt.;
dimethyl glutarate: 27 pts·wt.;
ethylene glycol: 0.3 pts·wt.;
MDI resin: 4 pts·wt.;
high molecular surface active agent: 3 pts·wt.; and
N, N-dimethylaminohexanol: 0.1 pts·wt.

Molded bodies to obtain the temporary fixation substrates 1 in Examples 1 to 6 and Comparative Examples 1 and 2 were prepared by mold casting using the prepared slurry. The mold 50 of an aluminum alloy was used. In this case, the temporary fixation substrates 1 eventually obtained differed in shape in the thin region RE while each having a diameter of 300 mm, having a thickness of 1.00 mm, and having a width “a” of the thin region of 4.5 mm except for Comparative Example 2.

In Examples 1, 2, and 5 and Comparative Example 1, molded bodies were prepared to obtain temporary fixation substrates 1 each including only the front side thickness-reduced portion 2a in the tapered shape as illustrated in FIG. 2A. In this case, the front recess amount Δta as the total recess amount Δt was 5 μm or less in each of Examples 1, 2, and 5 and was more than 10 μm in Comparative Example 1.

In Example 3, molded bodies were prepared to obtain temporary fixation substrates 1 each including only the front side thickness-reduced portion 2a in the stepped shape as illustrated in FIG. 2C. In this case, the front recess amount Δta as the total recess amount Δt was 5 μm or less.

In Example 4, molded bodies were prepared to obtain temporary fixation substrates 1 each including the front side thickness-reduced portion 2a and the rear side thickness-reduced portion 2b each in the stepped shape as illustrated in FIG. 2D. In this case, the total recess amount Δt was 5 μm or less.

In Example 6, molded bodies were prepared to obtain temporary fixation substrates 1 each including the front side thickness-reduced portion 2a and the rear side thickness-reduced portion 2b each in the tapered shape as illustrated in FIG. 2B. In this case, the total recess amount Δt was 5 μm or less.

In Comparative Example 2, molded bodies were prepared so that the front side thickness-reduced portion 2a and the rear side thickness-reduced portion 2b were not formed.

In any case, in preparing a molded body, the slurry was cast into the internal space 50s of the mold 50 at a room temperature, was allowed to stand at the room temperature for one hour and was then allowed to stand at 40° C. for 30 minutes. The slurry thereby allowed to set to some extent was released from the mold 50 and was allowed to stand sequentially at the room temperature for two hours and at 90° C. for two hours. The molded body was obtained by the above-mentioned processing.

Each of the obtained molded bodies was calcined (prefired) at 1100° C. in air and was then fired at 1750° C. in an atmosphere having a ratio of hydrogen to nitrogen of 3:1. Annealing was then performed in the same atmosphere and at the same temperature to obtain a sintered body.

The sintered body was lapped using a diamond slurry having a diamond grain diameter of 6 μm and was then cleaned, thereby to obtain each of the temporary fixation substrates 1 in Examples 1 to 6 and Comparative Examples 1 and 2.

For one of the obtained temporary fixation substrates 1 in each of Examples 1 to 6 and Comparative Examples 1 and 2, the front recess amount Δta and the rear recess amount Δtb were measured by a spectral-interference laser displacement meter including an infrared SLD light source having a center wavelength of 820 nm, and the total recess amount Δt was calculated. Specifically, the front surface and the rear surface of the temporary fixation substrate 1 were irradiated with laser to measure the shape, and the shape was compared with a reference block gauge to obtain the front recess amount Δta and the rear recess amount Δtb.

FIG. 8 is a diagram illustrating measurement positions of the front recess amount Δta. In measuring the front recess amount Δta, the temporary fixation substrate 1 was first mounted horizontally so that the front surface 1a was an upper surface. In this state, difference values of height positions at four measurement points A, B, C, and D spaced circumferentially at equal angular intervals in the front side thickness-reduced portion 2a in the thin region RE as an annular circumferential end of the temporary fixation substrate 1 from a height position in the region other than the thin region RE were measured by the laser displacement meter. An average value of the difference values at the four measurement points A, B, C, and D was determined to be the front recess amount Δta. In the case that the front side thickness-reduced portion 2a was tapered, the four measurement points A, B, C, and D were radially end positions of the front side thickness-reduced portion 2a.

When only the front side thickness-reduced portion 2a was formed in the thin region RE, the front recess amount Δta was the total recess amount Δt as it was.

On the other hand, when the rear side thickness-reduced portion 2b was formed in addition to the front side thickness-reduced portion 2a, the rear side thickness-reduced portion 2b was similarly subjected to measurement by the laser displacement meter as illustrated in FIG. 8 to calculate the rear recess amount Δtb, and the sum of the front recess amount Δta and the rear recess amount Δtb was determined to be the total recess amount Δt.

Each of the obtained temporary fixation substrates 1 was subjected to temporary fixation of the semiconductor chips 4 by the resin mold 6, grinding of the resin mold 6, formation of the cut lines CL, and laser lift-off according to the process illustrated in FIGS. 3A to 3C and 4A to 4C. The semiconductor chips 4 were arranged also in the thin region RE.

For each of Examples 1 to 6 and Comparative Examples 1 and 2, grindability of the resin mold 6 was evaluated based on a rate of a failure (failure rate) occurring during grinding of the resin mold 6 in a total of 200 test samples. In evaluation, it was determined that the failure occurred when the semiconductor chips 4 arranged in the thin region RE were not exposed despite a predetermined amount of grinding performed to originally expose all the semiconductor chips 4.

Peeling property of the temporary fixation substrate 1 was also evaluated based on a rate of a failure (failure rate) occurring during peeling of the temporary fixation substrate by laser lift-off. In evaluation, it was determined that the failure occurred when a resin component derived from the resin mold 6 or the adhering layer 3 adhered to the temporary fixation substrate 1 after peeling.

Table 1 shows a list of the total recess amount Δt (simply “TOTAL RECESS AMOUNT” in Table 1), a result of evaluation of peeling property of the temporary fixation substrate, and a result of evaluation of grindability of the resin mold for each of Examples 1 to 6 and Comparative Examples 1 and 2.

TABLE 1

| | TOTAL | | |
|---|---|---|---|
| | RECESS | PEELING | |
| | AMOUNT | PROPERTY | GRINDABILITY |
| | [μm] | EVALUATION | EVALUATION |
| EXAMPLE 1 | 2.2 | ∘ | ∘ |
| EXAMPLE 2 | 3.1 | ∘ | ∘ |
| EXAMPLE 3 | 3.7 | ∘ | ∘ |
| EXAMPLE 4 | 4.9 | ∘ | ∘ |
| EXAMPLE 5 | 3.3 | ∘ | ∘ |
| EXAMPLE 6 | 4.8 | ∘ | ∘ |
| COMPARATIVE | 10.4 | ∘ | x |
| EXAMPLE 1 | | | |
| COMPARATIVE | 0 | Δ | ∘ |
| EXAMPLE 2 | | | |

In evaluation of grindability of the resin mold 6 and peeling property of the temporary fixation substrate 1, when the failure rate was less than 3%, grindability and peeling property were evaluated to be good as the occurrence of the failure was suitably suppressed. In Table 1, the evaluation result is marked with a circle.

When the failure rate was 3% or more and less than 5%, grindability and peeling property were evaluated to be insufficient while the occurrence of the failure was suppressed to some extent. In Table 1, the evaluation result is marked with a triangle.

When the failure rate was 5% or more, the occurrence of the failure was evaluated not to be suppressed. In Table 1, the evaluation result is marked with a cross.

As can be seen from Table 1, both peeling property and grindability were evaluated to be good in Examples 1 to 6 in each of which the total recess amount Δt was 1 μm or more and 5 μm or less.

In contrast, in Comparative Example 1 in which the total recess amount Δt was 10.4 μm, which was large, peeling property was good, but many failures occurred in grinding the resin mold 6.

In Comparative Example 2 in which the thin region RE was not formed (the total recess amount Δt was zero), grindability was good, but more peeling failures occurred compared with those in each of Examples 1 to 6, and peeling property was insufficient.

The above-mentioned results show that the thin region RE formed at the circumference of the temporary fixation substrate 1 so that the total recess amount Δt is 1 μm or more and 5 μm or less is suitable to suppress the occurrence of the peeling failure during laser lift-off while securing grindability of the resin mold.

What is claimed is:

1. A temporary fixation substrate, peeled from a predetermined object to be fixed after once the predetermined object to be fixed is temporarily fixed to one main surface thereof, the temporary fixation substrate comprising:
a thin region being an annular region having a predetermined width from a lateral end; and
a first thickness-reduced portion on a side of the one main surface in the thin region, the first thickness-reduced portion having been recessed from the one main surface, wherein
a thickness in the thin region is smaller than a thickness in a region other than the reduced thickness region, and
a difference between a thickness at the lateral end and the thickness in the region other than the reduced thickness region is 1 μm to 5 μm.

2. The temporary fixation substrate according to claim 1, further comprising
a second thickness-reduced portion on a side of the other main surface in the thin region, the second thickness-reduced portion having been recessed from the other main surface, wherein
the sum of a front recess amount and a rear recess amount is 1 μm to 5 μm, the front recess amount being an amount by which the first thickness-reduced portion has been recessed from the one main surface at least at the lateral end, the rear recess amount being an amount by which the second thickness-reduced portion has been recessed from the other main surface at least at the lateral end.

3. The temporary fixation substrate according to claim 2, wherein
the first thickness-reduced portion and the second thickness-reduced portion are tapered.

4. The temporary fixation substrate according to claim 2, wherein
the first thickness-reduced portion and the second thickness-reduced portion are stepped.

5. The temporary fixation substrate according to claim 1, wherein
the temporary fixation substrate is disc-shaped, and
the predetermined width of the thin region is 0.5% or more and 3% or less of a radius of the temporary fixation substrate.

6. A method of manufacturing a temporary fixation substrate, peeled from a predetermined object to be fixed after once the predetermined object to be fixed is temporarily fixed to one main surface thereof, wherein
the temporary fixation substrate comprises:
a thin region being an annular region having a predetermined width from a lateral end; and
a first thickness-reduced portion on a side of the one main surface in the thin region, the first thickness-reduced portion having been recessed from the one main surface,
a thickness in the thin region is smaller than a thickness in a region other than the thin region,
a difference between a thickness at the lateral end and the thickness in the region other than the thin region is 1 μm to 5 μm, and
the method comprises:
a) performing mold casting of casting a raw material slurry containing powder of translucent ceramics using a mold and allowing the slurry to set to prepare a molded body containing the translucent ceramics as a major component and having a shape according to the temporary fixation substrate;
b) firing the molded body to obtain a sintered body;
c) chamfering a corner of the sintered body; and
d) polishing the chamfered sintered body.

7. A method of manufacturing a temporary fixation substrate, peeled from a predetermined object to be fixed after once the predetermined object to be fixed is temporarily fixed to one main surface thereof, wherein
the temporary fixation substrate comprises:
a thin region being an annular region having a predetermined width from a lateral end; and
a first thickness-reduced portion on a side of the one main surface in the thin region, the first thickness-reduced portion having been recessed from the one main surface,
a thickness in the thin region is smaller than a thickness in a region other than the thin region,
a difference between a thickness at the lateral end and the thickness in the region other than the thin region is 1 μm to 5 μm, and
the method comprises:
a) preparing a molded body containing translucent ceramics as a major component and then deforming the molded body into a shape according to the temporary fixation substrate;
b) firing the molded body to obtain a sintered body;
c) chamfering a corner of the sintered body; and
d) polishing the chamfered sintered body.

8. The method of manufacturing the temporary fixation substrate according to claim 7, wherein
the step a) comprises:
a-1) casting a raw material slurry containing powder of the translucent ceramics using a mold and allowing the slurry to set to obtain the molded body; and
a-2) pressing the molded body obtained in the step a-1) to deform the molded body.

9. The method of manufacturing the temporary fixation substrate according to claim 7, wherein
the step a) comprises:
a-1) molding a raw material slurry containing powder of the translucent ceramics into a plurality of pieces of tape;
a-2) laminating and integrating the plurality of pieces of tape to obtain a laminate;
a-3) punching the laminate to obtain the molded body; and
a-4) pressing the molded body obtained in the step a-3) to deform the molded body.
